(19) United States
(12) Patent Application Publication
(10) Pub. No.: US 2007/0068558 A1
(43) Pub. Date: Mar. 29, 2007

(54) Apparatus and methods for mask cleaning

(75) Inventors: James S. Papanu, San Rafael, CA (US); Roman Gouk, San Jose, CA (US); Han-Wen Chen, San Mateo, CA (US); Phillip Peters, Santa Clara, CA (US)

Correspondence Address: Michael A. Bernadicou;BLAKELY SOKOLOFF TAYLOR & ZAFMAN, Seventh Floor, 12400 Wilshire Boulevard, Los Angeles, CA, 90025-1030, US

(73) Assignee: APPLIED MATERIALS, INC.

(21) Appl. No.: 11/514,663

(22) Filed: Sep. 1, 2006

Related U.S. Application Data
(60) Provisional application No. 60/716,159, filed on Sep. 6, 2005.

(51) Int. Cl. G03F 1/00; B08B 3/00

(52) U.S. Cl. 134/29; 430/5; 134/26

(57) ABSTRACT

An integrated substrate cleaning processes capable of removing residues and particulates from the surface of a photomask is described. In one embodiment, an ozonated de-ionized water treatment is the first wet cleaning operation. In an embodiment of the present invention, the substrate cleaning process includes a wet cleaning operation employing an ammonium hydroxide-based chemical cleaning solution diluted with hydrogenated de-ionized water. In another embodiment of the present invention, the substrate cleaning process uses a plasma treatment prior to the first wet cleaning operation.

This application claims priority from U.S. Provisional Patent Application Ser. No. 60/716,159, filed Sep. 6, 2005.

### BACKGROUND OF THE INVENTION

1. Field of the Invention

The present invention relates to the field of electronics manufacturing industry and more particularly to the cleaning of photomasks.

2. Discussion of Related Art

Lithographic photomasks must be periodically cleaned during their manufacture as well as during their use in subsequent manufacturing processes. Because photomasks are repetitively imaged during their lifetime, a single defect can have an astounding cumulative effect on line yields. Therefore, a photomask cleaning method ideally has a very high defect removal efficiency, meaning the cleaning method removes a high percentage of the defects present on a photomask prior to the cleaning.

Defects may be in the form of particulates or haze. Haze is typically the result of a chemical film or residue adsorbed to the photomask surface. For 65 nm lithography technology nodes and below, the processes used to clean photomasks become ever more critical because photon interaction with mask cleaning chemistry residues become more problematic as exposure wavelengths shrink. Photomask cleaning processes therefore ideally leave no chemical residues on the photomask surface.

Conventional wet cleaning of photomasks typically includes processing the substrate with wet chemicals in a batch-substrate mode. A batch-substrate apparatus processes multiple photomasks in parallel through a sequence of chemical baths. As depicted in FIG. 1, a typical chemical clean sequence 100 includes an exposure to a sulfuric acid (H₂SO₄)-peroxide mixture (SPM) in a first clean operation 101, followed by an exposure to an ammonium hydroxide (NH₄OH)-peroxide mixture (SC1) at a second clean operation 105, final water rinse operation 110, and concluded with a drying operation 115. It has been found that such methods provide inadequate particle removal and also leave chemical residues, such as sulfur and ammonia, on the photomask surface which can cause haze and sub-pellicle defects during 193 nm lithographic exposures. The inadequacy of conventional cleaning techniques is expected to become even greater for 157 nm lithography. Thus, there remains a need for a photomask cleaning process that has both a high particle removal efficiency and leaves the photomask surface free of haze-producing chemical residues.

### SUMMARY OF THE INVENTION

Embodiments of the present invention are integrated substrate cleaning processes capable of removing residue and particulates from the surface of a photomask to be cleaned. In embodiments of the present invention, the substrate cleaning process is performed on a system comprising both wet cleaning modules and dry cleaning modules.

In an embodiment of the present invention, the first wet cleaning operation is an ozonated de-ionized water treatment.

In another embodiment of the present invention, the substrate cleaning process utilizes a hydrogen-based plasma treatment prior to the first wet cleaning operation.

In yet another embodiment of the present invention, the substrate cleaning process includes at least one wet cleaning operation employing an ammonium hydroxide-based chemical cleaning solution diluted with de-ionized water containing hydrogen. In a further embodiment of the present invention, the fluid applied to the front or backside of substrate is heated to a temperature above ambient.

### BRIEF DESCRIPTION OF THE DRAWINGS

FIG. 1 is a flow chart of a conventional method for cleaning photomasks.

FIGS. 2A-2E are illustrations of cross sections of a subset of the photomask substrates for which the present invention may be adapted.

FIG. 3 is a flow chart of an integrated photomask cleaning method in accordance with the present invention.

FIG. 4 is an illustration of a cross-sectional view of a single-substrate wet chemical processing module with which the present invention may be practiced.

FIGS. 5a and 5b are illustrations of a plan view of the plate upon which the photomask is position during wet cleaning in accordance with the present invention.

FIG. 6 is an illustration of a cross-sectional view of a venturi that may be used in accordance with the present invention.

FIGS. 7a, 7b, and 7c are illustrations of cross-sectional views of a membrane that may be used in accordance with the present invention.

FIG. 8 is an illustration of an integrated wet cleaning and dry cleaning apparatus with which the present invention may be practiced.

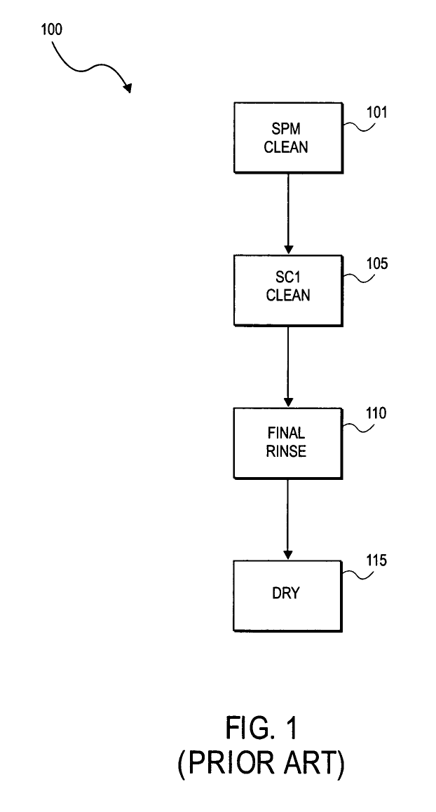

### DETAILED DESCRIPTION OF THE PRESENT INVENTION

In various embodiments, novel substrate processing methods are described with reference to figures. However, various embodiments may be practiced without one or more of these specific details, or in combination with other known methods, materials, and apparatuses. In the following description, numerous specific details are set forth, such as specific materials, dimensions and processes parameters etc. in order to provide a thorough understanding of the present invention. In other instances, well-known semiconductor processes and manufacturing techniques have not been described in particular detail in order to not unnecessarily obscure the present invention. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, materials, or characteristics may be combined in any suitable manner in one or more embodiments.

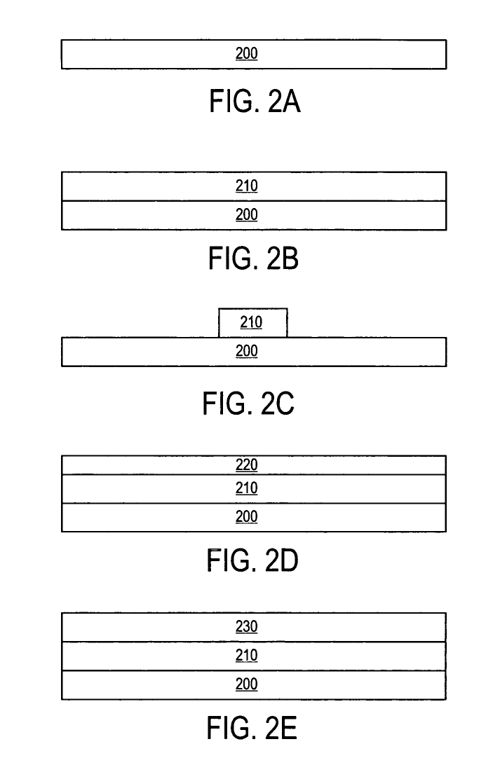

Embodiments of the present invention are integrated substrate cleaning processes capable of removing residue and particulates from the surface of a photomask. A photomask is used in lithography operations to replicate features of the photomask onto various manufacturing substrates, such as integrated circuits on wafers. A photomask is itself a substrate which must first be patterned with the specific features to be replicated by the photomask. Binary photomasks are comprised of features formed on a substrate. Generally, the features are opaque to the light used to project the photomask pattern while the substrate is transparent to the imaging light. Other technologies, such as phase shift, utilize modifications in the substrate thickness to improve feature resolution. Typical photomask substrates are shown in FIGS. 2A-FIG. 2E. As shown in FIG. 2A, photomask substrate 200 is commonly a glass or quartz substrate. Upon the substrate 200, layer 210 is formed over the “front side” of substrate 200, as shown in FIG. 2B. Layer 210 typically comprises Chromium (Cr) metal, but may also comprise other materials, such as iron oxide used when it is necessary to have a partially transparent medium. The photomask at this stage is commonly referred to as a photomask “blank.” In FIG. 2C the photomask blank may then have the desired pattern formed in layer 210 using commonly known techniques, such as e-beam lithography, to form a pattern in the front side of the photomask. The “back side” of the photomask substrate 200 refers to the non-patterned side. As shown in FIG. 2D, additional layers make be utilized prior to patterning the blank to form features having a composite structure for improved optical performance. For example, an anti-reflective layer 220 may be formed of a chrome oxide. Additionally, as shown in FIG. 2E, the photomask substrate 200 comprises a molybdenum silicide (MoSi) layer 230 upon which Cr layer 210 is applied to form a dual layer structure which can then be patterned. Thus, because defects can accumulate on either the back side or front side of a photomask, there may be a number of materials present on the photomask surfaces which must be cleaned. The photomask materials specifically described, well as other variations commonly known in the art, combine to form “substrates” for which the process herein described is well suited. It should be appreciated however, that the cleaning methods disclosed are adaptable to other “substrates” presenting similar materials to the surface to be cleaned such as, but not limited to, semiconductor wafers, compact disc or LCD display panels.

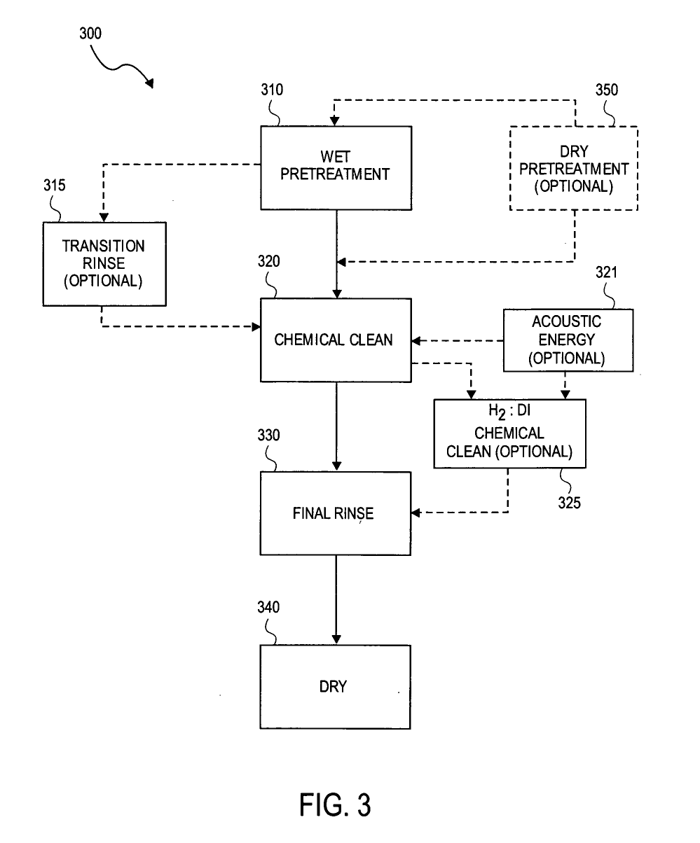

As shown in FIG. 3, an embodiment of the present invention is cleaning process 300 wherein the substrate is first pretreated with a process rendering the substrate surfaces hydrophilic. As shown in FIG. 3, either a wet pretreatment 310 or a dry pretreatment 350 is employed. In a particular embodiment, wet pretreatment comprises ozonated de-ionized water. In another embodiment, dry pretreatment 350 comprises a plasma of hydrogen or water vapor. Following the pretreatment, the substrate receives an “AM-Clean” chemical clean 320. Between the wet pretreatment and the AM-Clean, the substrate may optionally receive a transition rinse 315. Following the AM-Clean, a second chemical clean 325 is optionally performed prior to a final rinse 330 and dry 340. In a particular embodiment, second chemical clean 325 includes hydrogenated de-ionized water.

Throughout the detailed description of each operation in process 300, specific references will be made to single-substrate embodiments which employs a single-substrate apparatus to processes an individual substrate through a sequence of chemical treatments. It should be appreciated however, that process 300 is also adaptable to batch cleaning tools. A batch-substrate apparatus processes multiple substrates in parallel through a sequence of chemical baths.

Both the wet pretreatment 310 and dry pretreatment 350 improve the ability of the subsequent wet cleaning operations to wet the substrate surface by rendering the substrate surface hydrophilic. The pretreatment reduces the tendency of subsequent wet cleans to leave streaks of residue and particles on the substrate surface. Pretreatment operations 310 and 350 may be used in the alternative or in series. One advantage of wet pretreatment 310 over dry pretreatment 350 is that both sides of the substrate may be treated simultaneously. In one embodiment, the substrate is exposed to wet pretreatment 310 comprising ozonated de-ionized water for between approximately 20 seconds and 120 seconds. Ozone (O₃) is useful for pretreatment because it is a stronger oxidizer than many other chemical oxidizers such as peroxide. Ozonated de-ionized water provides a sufficiently reactive oxidizing media to leave the substrate surfaces hydrophilic. Ozonated de-ionized water also serves to oxidize organic contaminants on the substrate surface. Ozonated water can be formed by dissolving O₃ in degassed water, as discussed in more detail below. The concentration of dissolved ozone may be between 1 ppm and 200 ppm. Alternatively, the water may be saturated with the gas. In particular embodiments, the ozone concentration is between 20 ppm and 60 ppm.

In an embodiment of the present invention, a dry pretreatment 350 is performed to help render the substrate surface hydrophilic. As shown in FIG. 3, this plasma pretreatment may or may not be in addition to the wet pretreatment 310. In an embodiment where a plasma pretreatment is performed in addition to the wet pretreatment 310, the plasma pretreatment is performed prior to the wet pretreatment. In other embodiments, the dry pretreatment is used in absence of wet pretreatment 310. A careful selection of the gas chemistry is required for dry pretreatment 350 because many substrate surfaces, such as the photomask chromium oxide ARC 220 of FIG. 2D, can be damaged by plasma oxidation. A hydrogen-based plasma can help render the surface hydrophilic without causing the substrate surface oxidation that generally occurs with an oxygen (O₂) based plasma. In certain embodiments of the present invention, the plasma pretreatment exposes the substrate to a plasma generated with a hydrogen source gas, such as H₂ or H₂O (water vapor) with or without an inert, such as nitrogen (N₂). In a particular embodiment, a volumetric flow ratio of H₂ or H₂O to N₂ is between about 6:1 to about 200:1. For a 5-liter process chamber, a suitable gas flow rate comprises 500 sccm to 3000 sccm H₂ or H₂O. The plasma may be remotely generated as is commonly known in the art with an RF or microwave generator at a power level of between 200 to 3000 watts and introduced to the substrate in the cleaning chamber at a pressure of about 2 Torr for about 15 seconds. In further embodiments, the substrate may be heated during the plasma pretreatment to a temperature of between 50° C. and 200° C.

In still another embodiment, dry pretreatment 350 comprises exposing the substrate to ultraviolet (UV) energy (not shown). UV has also been determined to be capable of rendering the substrate surface hydrophilic and provide for improved wetting of subsequent wet cleaning operations. UV treatments of the photomask may be performed with any commonly known technique.

Another embodiment of the present invention employs a transition rinse 315 following the wet pretreatment 310 and before chemical cleaning operation 320. In a particular embodiment, the transition rinse is performed for between 10 seconds and 60 seconds. Transition rinse 315 serves to eliminate any deleterious effects ozone may have on the chemistry of the subsequent chemical cleaning operation. In particular embodiments, the transition rinse 315 comprises de-ionized water “gasified” to contain CO₂. The presence of CO₂ ensures the water remains sufficiently conductive that static charge does not build up on the substrate surface during processing. In a further embodiment, the de-ionized water is heated to between 40° C. and 80° C. to help make the transition rinse 315 more effective at eliminating residual ozone from the substrate surface. This elevated temperature can therefore result in a shorter total processing time.

Embodiments of the present invention include chemical clean operation 320. In certain embodiments, chemical clean 320 comprises an SC1 chemistry. In other embodiments of the present invention, other commonly known cleaning chemistries may be employed, such as but not limited to, SC2 and solvent cleans. In a particular embodiment, an ammonium hydroxide (NH₄OH) chemistry referred herein as “AM-Clean” is employed. AM-Clean is a mixture of ammonium hydroxide (NH₄OH), hydrogen peroxide (H₂O₂), water (H₂O), a chelating agent, and a surfactant.

The purpose of the ammonium hydroxide and the hydrogen peroxide in the AM-Clean solution is to remove particles and residual organic contaminates from the substrate surface. According to an embodiment of the present invention, the cleaning solution has an alkaline pH level of between 9 and 12 and more specifically between 10 and 11 due to the presence of the ammonium hydroxide and the hydrogen peroxide.

The purpose of the chelating agent in the AM-Clean is to remove metallic ions from the wafer. Chelating agents are also known as complexing or sequestering agents. These agents have negatively charged ions called ligands that bind with charged ions and form a combined complex that remains soluble. Common metallic ions that may be present on the substrate surface are copper, iron, nickel, aluminum, calcium, magnesium, and zinc, but other metallic ions may also be present. Suitable chelating agents include polyacrylates, carbonates, phosphonates, and gluconates. The advantages of using chelating agents to remove metallic impurities are that they do not require an acidic environment and that they reduce the overall cleaning time. Other methods of removing metallic ions, such as the commonly known SC2 solution, require an acidic environment. The acidic environment is incompatible with the alkaline environment of NH₄OH-based cleaning solutions. Chelating agents thus enable metallic ion removal to occur in a single alkaline cleaning step to reduce the overall cleaning time.

The purpose of the surfactant in the AM-Clean is to prevent reattachment or redeposition of particles on the wafer after they have been dislodged from the wafer. Preventing the reattachment of the particles is important to reducing overall cleaning times. A typical concentration range of the surfactant in the cleaning solution can be between 1 ppm and 100 ppm. In an embodiment of the present invention the surfactant is an anionic compound called MCX-SD 2000 as manufactured by Mitsubishi Chemical Corporation of Tokyo, Japan.

In a particular embodiment, the ammonium hydroxide in AM-Clean solution is from a solution of 28-29% w/w of NH₃ to water and the hydrogen peroxide is from a solution of 31-32% w/w of H₂O₂ to water. As well known in the art, these compounds only dissociate into their respective ions and no chemical reactions occur among these compounds. In various embodiments, the ammonium hydroxide (NH₄OH), hydrogen peroxide (H₂O₂), water (H₂O) are present in concentrations defined by dilution ratios of between 1/1/5 to 1/1/1000, respectively. The ammonium hydroxide/hydrogen peroxide ratio can also be varied between 0.05/1 and 1/1 and in some cases no hydrogen peroxide is used at all. In a particular embodiment, the AM-Clean chemistry comprises a mixture of 1:2:80 by volume of an aqueous solution of NH₄OH with surfactants and chelating agents available under the trade name “AM1” as manufactured by Mitsubishi Chemical, Tokyo, Japan, hydrogen peroxide (H₂O₂) and de-ionized water, respectively.

In an embodiment of the present invention, the substrate is exposed to the AM-Clean for between 60 seconds and approximately 240 seconds. In further embodiments the AM-Clean solution may be heated to between 25° C. and 60° C. Heating of AM-Clean solution is beneficial for removal of contaminants from the surface of the substrate and enables a reduction in total processing time. Too high of a temperature however is to be avoided as photomask ARC layers, if present on the substrate, can be damaged by high temperature cleans having chemistries similar to AM-Clean. Also, phase shift may occur when a relatively long high temperature AM-Clean is performed because AM-Clean at elevated temperatures has a non-negligible photomask substrate etch rate. In another embodiment of the present invention, acoustic energy 321 is applied at an intensity of between 0.2 W/cm² to 2 W/cm² of substrate area. Acoustic energy applied during operation 320 further enhances cleaning effectiveness. In yet another embodiment, the water volume comprising the AM-Clean cleaning solution may further be gasified with hydrogen (H₂) to contain between 1 ppm and 2 ppm H₂.

As shown in FIG. 3, following chemical clean 320, the substrate may receive a final rinse 330 or optionally a second chemical clean 325. Generally, embodiments employing chemical clean 325 may utilize any commonly known cleaning chemistry suitable for the particular substrate surfaces, such as but not limited to, SC1, SC2, buffered etchants, or solvents. A particular embodiment employs an aqueous solution of NH₄OH with surfactants and chelating agents available under the trade name “AM1” as manufactured by Mitsubishi Chemical, Tokyo, Japan. In a further embodiment, chemical clean 325 is performed for between 60 seconds and 240 seconds.

In a particular embodiment of the present invention, chemical clean 325 comprises de-ionized water containing hydrogen (H₂). An embodiment of the present invention utilizes between 1 ppm and 5 ppm hydrogen (H₂) and more specifically between 1 ppm and 2 ppm H₂ dissolved in water. In a further embodiment, the hydrogenated water is then mixed with the cleaning chemistry to form the cleaning solution applied to the substrate at operation 325. Use of hydrogenated water has been found to improve the cleaning efficiency of certain chemistries such as AM1, particularly when acoustic energy is applied.

In a particular embodiment of the present invention, AM1 is diluted with hydrogenated water to between 200 ppm to 5000 ppm AM1 (by volume). This very dilute chemistry is less chemically aggressive than AM-Clean 320 which can allow the cumulative clean time to be of a longer duration without adversely affecting the physical properties of the photomask such as ARC layers and substrate thicknesses tuned for phase-shift. In a further embodiment, acoustic energy 321 is applied during chemical clean 325, as shown in FIG. 3, to improve the cleaning efficiency. The acoustic intensity ranges from between 0.2 W/cm² to 2 W/cm² of substrate area. The less chemically aggressive nature of chemical clean 325 when coupled with the physical cleaning action of acoustic energy changes the balance between chemical and physical cleaning modes to favor the physical mode relative to chemical clean 320. Thus, chemical clean 320 and chemical clean 325 may each be used once or in an alternating fashion for an arbitrary number of chemical and physical cleaning cycles. Repetitive alternating application of chemical cleans 320 and 325 has been found to be useful in cleaning photomasks without causing damage to the photomask surface. In still another embodiment, second chemical clean 325 may be performed at an elevated temperature. In such an embodiment, the cleaning solution is heated to be between 25° C. and 80° C. and more specifically between 40° C. and 65° C. The more dilute or less aggressive chemistry can also be applied to the substrate at a higher temperature without causing the surface damage that would occur for the AM-Clean chemistry if used at the same temperature. Because it has been found that elevated temperatures increase particle removal efficiency significantly, including an operation where the chemistry of the clean is tempered in favor of higher elevated temperature is useful in the cleaning process 300. Finally, use of a hydrogenated chemical clean 325 has been found beneficial to remove chemical residues left behind by chemical clean 320 from the substrate surface before final rinse 330. In a particular embodiment, both the elevated temperature and the dissolved hydrogen in chemical clean 325 help remove residual chemistry from the substrate. Additionally, a more gradual change in pH is possible when chemical clean 325 is included in clean process 300.

As shown in FIG. 3, final rinse 330 is performed subsequent to the last chemical clean operation. The photomask may be rinsed for around 20 seconds or more. The rinsing step after the cleaning step may remove all the chemical from the wafer surface, i.e. ammonium hydroxide, hydrogen peroxide, chelating agents, and surfactants. In a particular embodiment, the final rinse is performed with de-ionized water containing between 100 ppm and 2500 ppm carbon dioxide (CO₂) and more specifically between 1500 ppm and 2000 ppm. In an embodiment of the present invention, CO₂ is dissolved into DI water in an amount sufficient to dissipate static electricity. Static electricity builds up in the rinse water because of the rotation of the wafer between 10-1000 rpm. The presence of CO₂ ensures that the conductivity of the rinse water is sufficiently high to avoid damaging the substrate through electrostatic discharge (ESD) events. In a further embodiment, the rinse water has an elevated temperature between 25° C. and 80° C. to improve the ability to rinse off the cleaning chemicals from the surface of the substrate.

Following final rinse 330, a dry 340 is performed. Generally, the dry may be any commonly employed in the industry, such as, but not limited to, a spin dry and Marangoni dry. If desired, N₂ and/or IPA vapor may be blown on the substrate to assist in drying. After drying, cleaning process 300 is complete.

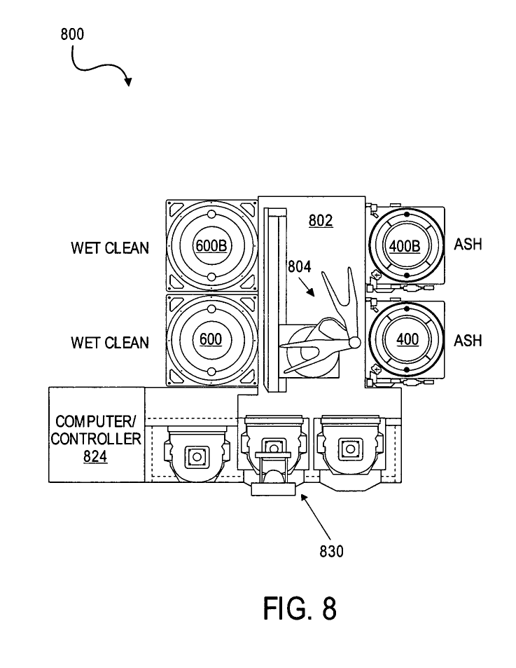

In an embodiment of the present invention, the integrated cleaning process 300 depicted in FIG. 3 is performed in a system comprising both a wet cleaning apparatus and a dry cleaning apparatus, as shown in FIG. 8. The integrated wet and dry cleaning platform 800 enables the plasma pretreatment 350 of FIG. 3 to be integrated with the wet cleaning operations of process 300 of FIG. 3. In one embodiment, system 800 includes a central transfer chamber 802 having a handling device 804 contained therein. The substrate, with or without a photomask adapter, is handled by the handling device 804. Directly attached to the transfer chamber 802 is a single substrate wet cleaning module 600 and a dry cleaning (ash) module 400. The wet cleaning module 600 and the dry cleaning module 400 are each connected to the transfer chamber 802 through a separately closable opening. In a further embodiment, a second wet cleaning module 600B and/or a second dry clean (ash) module 400B are also coupled to the transfer chamber 802. In another embodiment, also coupled to the transfer chamber 802 is at least one input/output 830 for providing substrates to and from system 800. In another embodiment, a system computer 824 is coupled to and controls each of the wet clean module 600 and dry clean (ash) module 400 as well as the operation of the transfer chamber 802 and handling device 804. In one embodiment, system computer 824, causes system 800 to place a substrate in dry clean module 400, expose the substrate to a H₂ or H₂O vapor plasma, and transfer the substrate from dry clean module 400 to wet cleaning module 600A. Once the substrate is in the wet cleaning module 600A, system computer 824 causes the wet cleaning module 600A to spin the substrate, apply an ozonated water pretreatment, apply a first and second cleaning solution comprising NH₄OH, final rinse and dry the substrate, remove the substrate from wet cleaning module 600A and transfer the substrate to input/output 830.

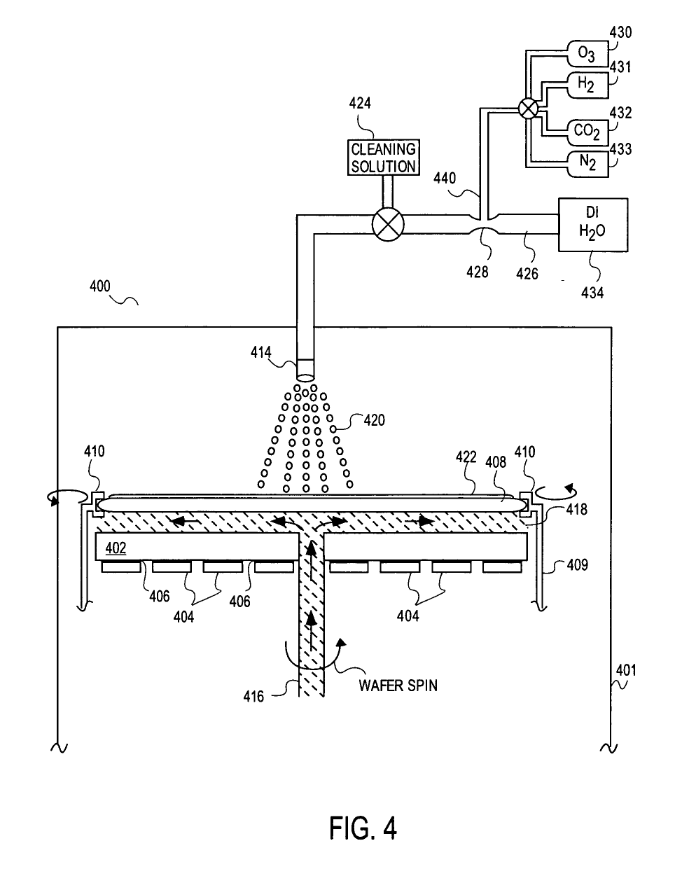

Referring back to FIG. 4, the substrate 408 in the wet cleaning apparatus is horizontally held by a support 409 parallel to and spaced-apart from the top surface of plate 402. In an embodiment of the present invention, substrate 408 is held about 3 mm above the surface of plate 402 during cleaning. In some embodiments, the substrate 408 is placed within an adapter configured for photomasks and is clamped front side up to support 409 by a plurality of clamps 410. In other embodiments no specific adapter is required to hold a photomask in place during processing. For example, the photomask can be supported on elastomeric pads on posts and held in place by gravity. The support 409 can horizontally rotate or spin the substrate 408 about its central axis at a rate of between 0-6000 RPM. One side of the substrate faces towards a nozzle 414 for dispensing de-ionized water or cleaning chemistry thereon and the back side of the substrate faces plate 402. During use, a spray 420 of droplets that form a liquid coating 422 on the top surface of the substrate 408 while substrate 408 is spun. Tank 424 containing the cleaning solution of the present invention is coupled to conduit 426 which feeds nozzle 414. Additional tanks (not shown) may provide alternate chemistry sources for embodiments employing a plurality of chemical cleaning operations. Additionally, single-substrate wet cleaning apparatus 400 can include a sealable chamber 401 in which nozzle 414, substrate 408, and plate 402 are located as shown in FIG. 4.

In an embodiment of the present invention de-ionized water or cleaning solution is fed through a channel 416 of plate 402 and fills the gap between the back side of substrate 408 and plate 402 to provide a water filled gap 418 through which acoustic waves generated by transducers 404 can travel to substrate 408. In embodiments flowing cleaning solution through channel 416 to fill gap 418, the back side of the photomask or substrate 408 is cleaned simultaneously with the front side clean. In particular embodiments of the present invention the fluid fed through channel 416 has a different temperature than the fluid applied to the front side of the substrate. This ability enables the temperature of substrate 408 to be controlled independently from the temperature of the cleaning solution applied to the front side of the substrate. For example, in a particular embodiment of the present invention, chemical clean 320 of FIG. 3 is performed with an AM-Clean solution heated to between 25° C. and 60° C. dispensed by nozzle 414 while 20° C. water or AM-Clean solution is flowed through channel 416. It is useful to control the substrate temperature with back side fluid flow through channel 416 in this manner because the anti-reflective coatings or phase shift on some photomasks (substrates) may be damaged by high temperature AM-Clean embodiments. In another embodiment, both the front side dispense from nozzle 414 and the back side dispense through channel 416 may be heated to approximately the same elevated temperature. For example, in a particular embodiment of the present invention, second chemical clean 325 of FIG. 3 is performed with a heated AM1 and hydrogenated water solution on both the front side and backside of substrate 408.

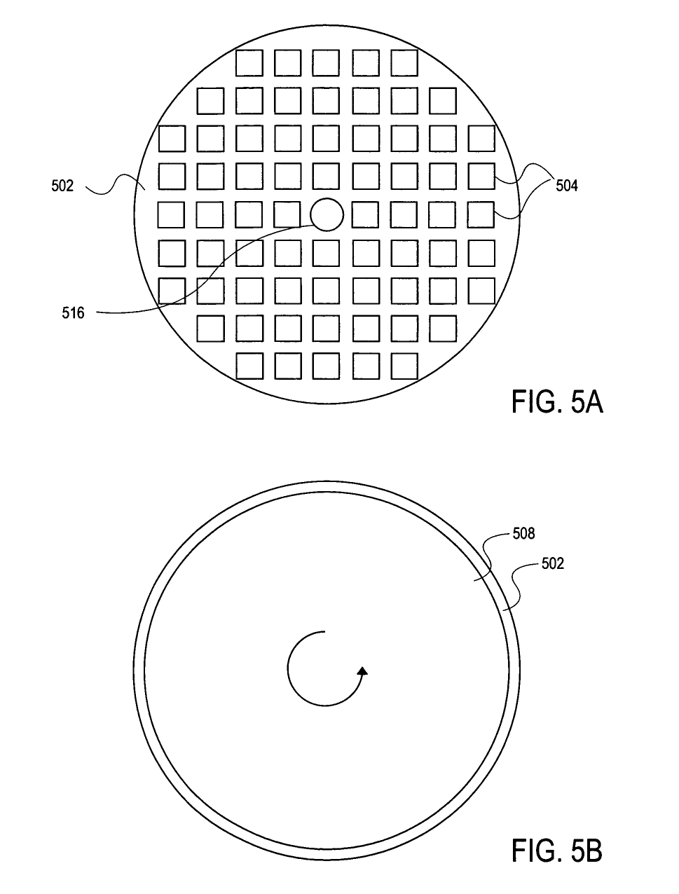

Throughout the cleaning process 300, and in particular chemical clean 320 and second chemical clean 325 shown in FIG. 3, acoustic energy may be applied via acoustic generators or transducers 404 attached to the bottom surface of plate 402 by epoxy 406. In an embodiment of the present invention, as shown in FIG. 5A, the transducers 504 cover substantially the entire bottom surface of plate 502 with a channel opening 516 to accommodate back side fluid flow. In an alternate embodiment of the present invention there are four transducers 504 covering the bottom surface of plate 502 in a quadrant formation and preferably covering at least 80% of plate 502. The transducers 504 preferably generate megasonic waves in the frequency range above 350 kHz. The specific frequency is dependent on the thickness of the substrate and is chosen by its ability to effectively provide megasonics to both sides of the substrate. But there may be circumstances where other frequencies that do not do this may be ideal for particle removal. In an embodiment of the present invention the transducers are piezoelectric devices. The transducers 504 create acoustic or sonic waves in a direction perpendicular to the major surfaces of substrate. The transducer cover plate 502 may, but need not, have substantially the same shape as photomask 508.

In an embodiment of the present invention, de-ionized water containing gas is employed in the cleaning process 300 of FIG. 3 to provide a chemically reactive agent as in the pretreatment 310, to improve cleaning efficiency when coupled with acoustic energy as in the chemical clean 320, or for both purposes as in the second chemical clean 325. As is understood in the art, gases dissolved in a fluid can result in cavitation upon application of acoustic energy which has been shown to increase the effectiveness of a cleaning process. In a particular embodiment, gas is mixed with water in-line wherein the source gas from travels through conduit 440 and is dissolved as it travels to nozzle 414. As it is important to control the concentration of the dissolved gas in the cleaning solutions, the incoming water is first degasified. Degassification may be accomplished with well-known techniques at either the point of use or up stream at the source. The degasified de-ionized source water 434 may then be controllably entrained with a specific concentration of a source gas such as, but not limited to, ozone (O₃) source 430, hydrogen (H₂) source 431, carbon dioxide (CO₂) source 432, and nitrogen (N₂) source 433.

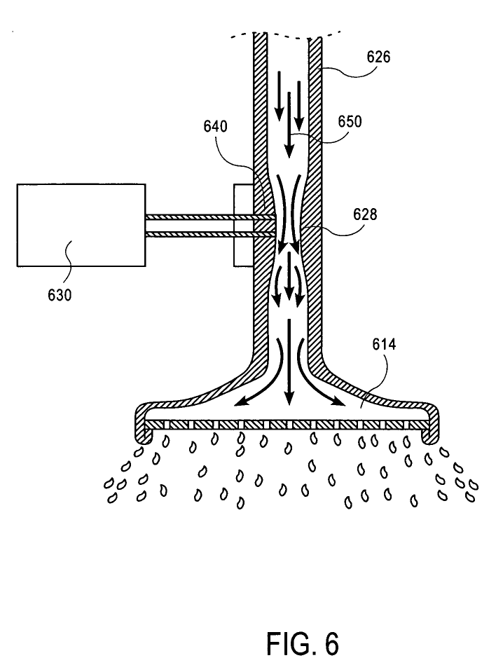

In one embodiment, gas is dissolved in the de-ionized source water 434 upstream of the cleaning solution tank 424 inlet, as shown in FIG. 4. Generally, gasification may be performed by any commonly known method. In a particular embodiment of the present invention, conduit 426 has a reduced cross-sectional area or “venturi” 428 in-line before spray nozzle 414. Referring to FIG. 6, a gas from source 630 travels through conduit 640 and is dissolved in the liquid 650 traveling in conduit 626 upstream from nozzle 614. Venturi 628 enables a gas to be dissolved into a fluid flow at a gas pressure less than the pressure of the liquid flowing through conduit 626.

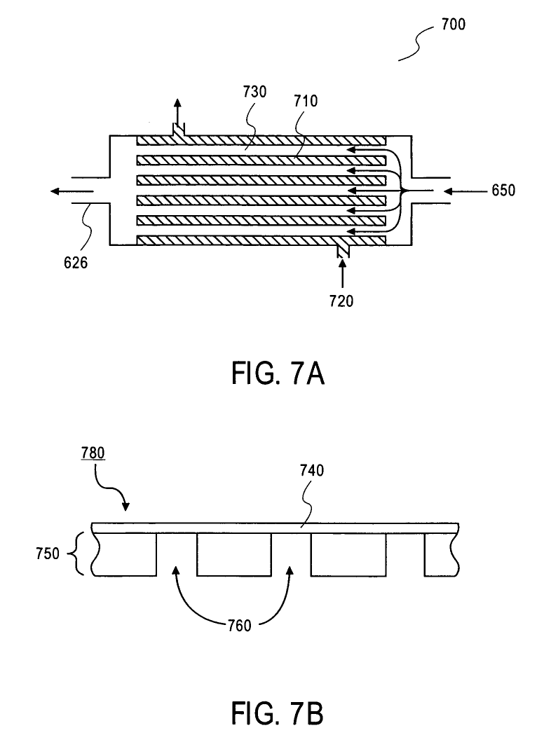

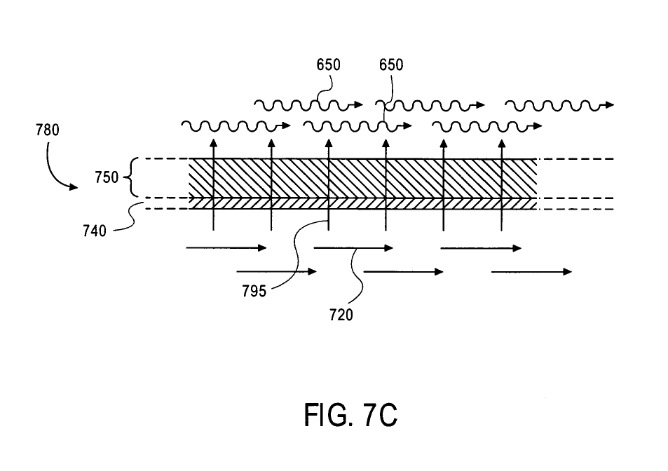

In an alternate embodiment, gases are dissolved into the cleaning solution by a hydrophobic contactor device 700 as shown in FIG. 7A. This contactor device 700 is put into the conduit 626. Contactor device 700 has a hydrophobic membrane conduit 710 which allows gasses to pass through but not water. Gas 720 is fed into membrane conduit 710 where the gas dissolves into the liquid 650 passing through the liquid conduit 730. Contactor device 700 includes a conduit or plurality of conduits 710 formed from a membrane stack 780 shown in FIG. 7B. The membrane stack 780 in contactor device 700 is a combination of porous polymeric membranes 750 and a solid very thin flouropolymer sheet 740, such as a PFA sheet as shown in a cross sectional view in FIGS. 7b. The thin solid membrane 740 prevents impurities in the gas from dissolving into the liquid. The thicker porous membrane 750 acts as a support for the thin membrane 740. The thicker porous membrane 750 has pores 760 on the order of 0.05 um. An example of a suitable contactor device 700, is the “Infuzor” made by Pall Corporation, Port Washington, N.Y. The polymeric membranes 740 and 750 are impermeable to liquids but permeable to gases. In an embodiment of the current invention, shown in FIG. 7C, the liquid 650 will flow along the thick membrane 750 and the gas 720 will flow along the thin membrane 740. The gas 795, minus any impurities, diffuses through the stacked membrane 780 and dissolves into the DI rinse water (liquid 650).

Although the present invention has been described in language specific to structural features and/or methodological acts, it is to be understood that the invention defined in the appended claims is not necessarily limited to the specific features or acts described. The specific features and acts disclosed are to be understood as particularly graceful implementations of the claimed invention in an effort to illustrate rather than limit the present invention.

What is claimed is:

1. A method of cleaning a photomask comprising:
exposing the photomask surface to an ozonated water pretreatment;
exposing the photomask surface to a cleaning solution comprising NH₄OH;
final rinsing the photomask with water; and
drying the photomask.

2. The method of claim 1, wherein the ozonated water pretreatment contains between 20 ppm and 60 ppm O₃.

3. The method of claim 1, further comprising a transition rinse following the ozonated water pretreatment, wherein the transition rinse exposes the photomask to water containing between 100 ppm and 2500 ppm CO₂.

4. The method of claim 3, wherein the transition rinse fluid has a temperature between 40° C. and 80° C.

5. The method of claim 1, wherein the cleaning solution further comprises:
one part by volume aqueous solution of 29% NH₄OH, surfactant, and chelating agents;
two parts by volume 32% H₂O₂;
and 80 parts by volume water.

6. The method of claim 5, wherein the cleaning fluid has a temperature between 40° C. and 60° C.

7. The method of claim 5, wherein the photomask is exposed to the cleaning fluid for approximately 120 seconds.

8. The method of claim 5, wherein the cleaning solution water contains between 1 ppm and 2 ppm H₂.

9. The method of claim 1, further comprising applying a second cleaning solution to the photomask surface, wherein the second cleaning solution is an aqueous solution of 29% NH₄OH, surfactants and chelating agents diluted to between 200 ppm to 5000 ppm with water containing between 1 ppm and 2 ppm H₂.

10. The method of claim 9, wherein the second cleaning solution is heated to between 40° C. and 60° C.

11. The method of claim 9, wherein the second cleaning solution is applied to the photomask surface for approximately 120 seconds.

12. The method of claim 1, further comprising the application of acoustic energy while the cleaning fluid is on the surface of the photomask, wherein the acoustic energy intensity is between 0.2 W/cm² and 2 W/cm².

13. The method of claim 1, wherein the cleaning solution has a temperature between 40° C. and 60° C.

14. The method of claim 1, further comprising applying a room temperature fluid to the back side of the photomask while exposing the front side of the photomask to the cleaning solution.

15. The method of claim 1, wherein the water for said final rinsing of the photomask contains between 100 and 2500 ppm CO₂.

16. A method of cleaning a photomask, comprising:
exposing the photomask to a plasma pretreatment;
exposing the photomask surface to a first cleaning solution comprising:
one part by volume aqueous solution of 29% NH₄OH, surfactant, and chelating agents;
two parts by volume 32% H₂O₂; and
80 parts by volume water;
exposing the photomask surface to a second cleaning solution, wherein the second cleaning solution is an aqueous solution of 29% NH₄OH, surfactants and chelating agents diluted to between 200 ppm to 5000 ppm with water containing between 1 ppm and 2 ppm H₂;
final rinsing the photomask with water; and
drying the photomask.

17. The method of claim 16, wherein the plasma pretreatment comprises a water vapor or H₂ plasma.

18. The method of claim 16, further comprising:
exposing the photomask surface to ozonated water following the plasma pretreatment and prior to exposing the photomask surface to the first cleaning fluid.

19. A machine-readable medium having stored thereon a set of machine-executable instructions that, when executed by a data-processing system, cause a system to perform a method to clean a photomask comprising:
placing a photomask into a single-substrate wet cleaning apparatus;
spinning the photomask in the single-substrate wet cleaning apparatus;
exposing the photomask to an ozonated water pretreatment containing between 20 ppm and 60 ppm ozone (O₃);
exposing the photomask to a cleaning solution comprising NH₄OH;
final rinsing the photomask with water;
drying the photomask;
and removing the photomask from the single-substrate wet cleaning apparatus.

20. The machine-readable medium of claim 19, further comprising exposing the photomask to a plasma pretreatment prior to placing the photomask into the single-substrate wet cleaning apparatus.
